(19) United States
(12) Patent Application Publication
(10) Pub. No.: US 2011/0068862 A1
(43) Pub. Date: Mar. 24, 2011

(54) FEEDBACK AMPLIFIER AND FEEDBACK AMPLIFICATION METHOD

(76) Inventor: HIROKAZU KOMATSU, Tokyo (JP)

(21) Appl. No.: 12/882,682

(22) Filed: Sep. 15, 2010

(30) Foreign Application Priority Data
Sep. 18, 2009 (JP) 216721/2009

(51) Int. Cl. H03F 3/45

(52) U.S. Cl. 330/69

(57) ABSTRACT

A feedback amplifier comprises a differential amplifier equipped with differential input terminals and differential output terminal and a first amplifier, wherein the differential output terminal is connected to input terminal of the first amplifier, wherein output terminal of the first amplifier is connected to one of the differential input terminals, and wherein the gain of the first amplifier decreases for lower frequency component of the signal which the differential amplifier outputs than a predetermined frequency when the output voltage of the differential output exceeds a predetermined value.

This application is based upon and claims the benefit of priority from Japanese Patent Application No. 2009-216721 filed on Sep. 18, 2009, the disclosure of which is incorporated herein in its entirety by reference.

### TECHNICAL FIELD

The present invention relates to a feedback amplifier and a feedback amplification method, in particular, relates to a feedback amplifier and a feedback amplification method which is used for a receiver of optical burst signal.

### BACKGROUND ART

Differential amplifiers are used in general for amplification of received optical signal in the receiver which handles the optical signal whose frequency is more than several MHz. In particular, it is desired for the burst signal receiver which amplifies the received optical burst signal to respond to the rapid amplitude change of the received optical signal.

The non-patent literature 1 discloses the structure of the optical signal receiver in which feedback signal, obtained from the differential output of the differential amplifier for amplifying the received signal, is amplified in DC (direct current) amplification circuit and fed back to the input of the differential amplifier after passing through a low pass filter.

FIG. 4 is a figure showing an example of the structure of a burst optical signal receiver 100, which is related to the present invention. In the burst optical signal receiver 100, the DC amplification circuit of the optical signal receiver described in the non-patent literature 1 is configured by well known inverse amplification circuit using operational amplifier and resistor component. The burst signal receiver 100 includes photodiode PD1, a transimpedance amplifier 10, a differential amplifier 20, an error signal amplification circuit 30 and a low pass filter 40. In the burst optical signal receiver 100, the error signal amplification circuit 30 corresponds to the DC amplification circuit in the non-patent literature 1. The burst signal receiver 100 converts the single end amplification to the differential amplification between the transimpedance amplifier 10 and the differential amplifier 20 using the error signal amplification circuit 30 and the low pass filter circuit 40.

The photodiode PD1 converts the input optical signal to the electric current signal whose amplitude is proportional to the strength of the input optical signal.

The transimpedance amplifier 10 converts the current signal obtained by the optical-to-electrical conversion into voltage signal using resistor R102. An inverting amplifier 101 is connected to resistor R102 in parallel. This configuration declines the input impedance of the transimpedance amplifier 10. As a result, it is possible to receive the high speed burst signal because the decline of the response speed caused by the input capacitance of photodiode PD1 and the transimpedance amplifier 10 is reduced.

The differential amplifier 20 includes a non-inverting input terminal 201, an inverting input terminal 202, a positive phase output terminal 203 and a reverse phase output terminal 204. The gain of the differential amplifier 20 is G2. The inverting input terminal 202 of the differential amplifier 20 is connected to the output of the transimpedance amplifier 10. The non-inverting input terminal 201 of the differential amplifier 20 is connected to the output of the low pass filter 40. On the other hand, a positive phase output terminal 203 and a reverse phase output terminal 204 of the differential amplifier 20 are connected to a signal processing circuit placed in the latter part of the burst signal receiver 100 as an output of the burst optical signal receiver 100. Furthermore, the positive phase output terminal 203 and the reverse phase output terminal 204 of the differential amplifier 20 are also connected to the error signal amplification circuit 30.

The error signal amplification circuit 30 includes an operational amplifier 301 and resistors R302-R305. The gain of the error signal amplification circuit 30 is G3. A positive phase input terminal 306 of the operational amplifier 301 is connected to the positive phase output terminal 203 of the differential amplifier 20 via resistor R302. A positive phase input terminal 306 of the operational amplifier 301 is grounded via resistor R303. A reverse phase input terminal 307 of the operational amplifier 301 is connected to the reverse phase output terminal 204 of the differential amplifier 20 via resistor R304. The reverse phase input terminal 307 of the operational amplifier 301 is connected to an output terminal 308 of the operational amplifier 301 via resistor R305.

The values of resistors R302, R303, R304 and R305 are set so that the gain of the error signal amplification circuit 30 will be G3. For example, in the circuit shown in FIG. 4, supposing that the resistance values of the resistors R302 and 8304 are R1 and the resistance values of the resistors R303 and R305 are R2, the gain G3 (absolute value) of the error signal amplification circuit 30 is given by the formula G3=R2/R1. The error signal amplification circuit 30 inversely amplifies the differential output voltage of the differential amplifier 20 to G3 times voltage.

The low pass filter 40 is the first order low pass filter having a resistor R401 with the resistance value R3 and a capacitor C402 with the capacitance value C1. The cutoff frequency f1 of the low pass filter 40 is given by f1=1/(2π×R3×C1). One of the terminals of the resistor R401 is connected to an output terminal 308 of the operational amplifier 301. Other terminal of the resistor R401 is grounded via the capacitor C402 and is connected to the non-inverting input terminal of the differential amplifier 20. In this way, the output of the error signal amplification circuit 30 is inputted to the differential amplifier 20 as a feedback signal.

Next, the operation of the burst signal receiver 100 will be described referring to FIG. 5 and FIG. 6a to FIG. 6d. FIG. 5 is a figure showing the frequency characteristics of the burst optical signal receiver 100, and FIG. 6a to FIG. 6d are figures showing signal waveforms inside the burst optical signal receiver 100.

FIG. 5 indicates the frequency characteristics of the gains of the differential amplifier 20 and the feedback circuit 50 composed of the differential amplifier 20, the error signal amplification circuit 30 and the low pass filter 40. In FIG. 5, the horizontal axis indicates frequency, and the vertical axis indicates the gain. The gain of the feedback circuit 50 is a constant value G1 in a frequency range lower than f1. When the frequency exceeds f1, the gain of the feedback circuit 50 declines at the inclination rate of 20 dB/dec towards the higher frequency band due to the characteristics of the low pass filter 40.

Further, the gain of the differential amplifier 20 shown in FIG. 5 indicates the gain in the state that the negative feedback is activated by the low pass filter 40. That is, the gain of the differential amplifier 20 is a constant value of G2 in the frequency band higher than f2. However, as will be mentioned later, in the frequency band lower than f2, the gain of the differential amplifier 20 decreases at the inclination rate of 20 dB/dec towards the lower frequency band.

As well known, the product of the gain and frequency of the feedback circuit 50 will be a constant value of f1×G1 in the frequency band where the gain decreases at the inclination rate of 20 dB/dec towards the higher frequency band. Accordingly, the unity gain frequency f2 where the gain of the feedback circuit 50 gets 1 will be f1×G1. In the lower frequency band than f2, the offset, which is generated in the photodiode PD1 and the transimpedance amplifier 10, is cancelled by the negative feedback operation of the feedback circuit 50.

When the output of the low pass filter 40 is fed back to the differential amplifier 20, the gain of the feedback circuit 20 decreases in the low frequency band where the gain of the differential amplifier 20 keeps plus. That is, the gain of the differential amplifier 20 is kept to be the constant value G2 in the high frequency band. However, the gain of the differential amplifier 20 decreases at the inclination rate of 20 dB/dec towards the low frequency band because the stronger feedback is applied by the output of the low pass filter 40 in the lower frequency band than f2.

FIG. 6a to FIG. 6d indicate the waveform and the value of the received data in each part of the burst signal receiver 100 when the optical burst signals with different amplitudes are supplied to photodiode PD1 of the burst optical signal receiver 100 described in FIG. 4. FIG. 6a indicates the waveform of optical burst signal input to photodiode PD1. FIG. 6b and FIG. 6c indicate the input waveform to the differential amplifier 20 and the output waveform of the differential amplifier 20 respectively. In FIG. 6b and FIG. 6c, the solid line represents a waveform of the non-inverting input/positive phase output terminals 201, 203 of the differential amplifier 20 and the broken line represents a waveform of the inverting input/reverse phase output terminals 202, 204 of the differential amplifier 20.

As shown in FIG. 6a and FIG. 6b, the output of the transimpedance amplifier 10 will be in the reverse phase for the optical input signal. The output of the transimpedance amplifier 10 is inputted to the differential amplifier 20. On the other hand, the output of the low pass filter 40 responds based on a time constant corresponding to frequency f2. Accordingly, the output of the low pass filter 40 reaches the output level of the transimpedance amplifier 10 based on a time constant which is relatively long.

The positive phase output waveform and the reverse phase output waveform of the differential amplifier described in FIG. 6c are symmetrical, and the polarities of the waveforms become inverse each other. Here, the time response behaviors of the positive and reverse phase output waveforms are the same.

FIG. 6d shows the polarity of the difference signal in the differential output of the differential amplifier 20. A signal processing circuit connected to the latter part of the differential amplifier determines whether received data is “0” or “1” based on the amplitude difference between the positive phase output and the reverse phase output.

The time period from the rising of positive phase and reverse phase waveforms indicated with an arrow in FIG. 6c until the crossing of both signal levels of the waveforms is called acquisition time of the response for the burst signal. In FIG. 6d, the difference signal of the differential output keeps the constant polarity during the acquisition time just after the amplitude of the received data decreases rapidly irrespective of whether the data is “0” or “1”. Hence, the signal cannot be normally reproduced out of the differential output during the acquisition time.

[The Preceding Technical Literature]

[Non-Patent Literature]

[Non-patent literature 1] Jens Mullrich et al., “High-Gain Transimpedance Amplifier in InP-Based HBT Technology for the Receiver in 40-Gb/s Optical-Fiber TDM Links”, IEEE JOURNAL OF SOLID-STATE CIRCUITS, USA, September 2000, VOL. 35, NO. 9, p. 1260-1265 (FIG. 2)

In the burst signal receiver 100 shown in FIG. 4, the frequency characteristics of the feedback circuit keeps constant without depending on the signal amplitude. Therefore, in the burst signal receiver 100 shown in FIG. 4, the acquisition time gets long when the signal with large amplitude is inputted just before receiving the burst signal with small amplitude. A problem takes place that the acquisition time gets long and the time period in which the signal cannot be normally reproduced becomes long when large amplitude signal is inputted in a case of the receiver whose response speed is low.

In addition, by employing the burst signal receiver with high speed response in order to shorten pull-in time with response improvement of the feedback signal to the amplitude change of the burst signal, data error may occur in case that “0” or “1” signals are continuously received especially in optical transmission systems using NRZ (Non-Return-to-Zero) code.

FIG. 12 indicates an example of input waveform of the differential amplifier in the burst signal receiver shown in FIG. 4 when “0” signal is continuously received. Solid lines indicate a received signal which is inputted to one input terminal of the differential amplifier while a broken line indicates a feedback signal which is inputted to other input terminal of the differential amplifier. In this way, when the response speed of the burst signal receiver is high; the amplitude of the feedback signal is close to the received signal amplitude during the same polarity data is received. And then, the feedback signal and the received signal are inputted to the differential amplifier in a manner that the feedback signal amplitude is almost the same as the received signal amplitude. As a result, the received data error occasionally takes place due to the inversion of the polarity of the differential output of the differential amplifier caused by the influence of noise and so on since both amplitudes of the received data and the feedback signal are almost the same in spite that the received data continues the same value. The same problem occurs when “1” signals are continuously received.

In this way, it is difficult to realize the coexistence of shortening the acquisition time and improving the code reproduction capability for receiving the continuous codes with the same polarity in the burst signal receiver 100 shown in FIG. 4.

### SUMMARY

An exemplary object of the invention is to provide a feedback amplifier and a feedback amplification method which can reduce the acquisition time when the input signal amplitude changes and have receiver tolerance for the data in which the same polarity signal continues.

A feedback amplifier to an exemplary aspect of the present invention comprises a differential amplifier equipped with differential input terminals and differential output terminal and a first amplifier, wherein the differential output terminal is connected to input terminal of the first amplifier, wherein output terminal of the first amplifier is connected to one of the differential input terminals, and wherein the gain of the first amplifier decreases for lower frequency component of the signal which the differential amplifier outputs than a predetermined frequency when the output voltage of the differential output exceeds a predetermined value.

A feedback amplification method to an exemplary aspect of the present invention comprises amplifying the difference between the first input and the second input and outputting the amplified difference between the first input and the second input as differential outputs, amplifying the difference between the differential outputs and outputting the amplified difference in the differential output as the first output, inputting the first output to said second input and reducing the gain of the amplifying the difference between the differential outputs for the lower frequency than a predetermined frequency of said differential output when the output voltage of the differential output exceeds a predetermined value.

### BRIEF DESCRIPTION OF THE DRAWINGS

Exemplary features and advantages of the present invention will become apparent from the following detailed description when taken with the accompanying drawings in which:

FIG. 1 shows the structure of a burst signal receiver of a first exemplary embodiment of the present invention;

FIG. 2 shows the frequency characteristics of a feedback circuit and a differential amplifier in the first exemplary embodiment;

FIG. 3a to FIG. 3d show signal waveforms in each part of a burst optical signal receiver of the first exemplary embodiment;

FIG. 4 shows an example of the structure of a burst optical signal receiver related to the present invention;

FIG. 5 shows the frequency characteristics of the burst optical signal receiver;

FIG. 6a to FIG. 6d show signal waveforms inside the burst optical signal receiver;

FIG. 7 shows the structure of a burst signal receiver of a second exemplary embodiment of the present invention;

FIG. 8 shows the structure of a burst signal receiver of a third exemplary embodiment of the present invention;

FIG. 9 shows the structure of a burst signal receiver of a fourth exemplary embodiment of the present invention;

FIG. 10 shows the structure of a burst signal receiver of a fifth exemplary embodiment of the present invention;

FIG. 11 shows the structure of a feedback amplifier of a sixth exemplary embodiment of the present invention;

FIG. 12 shows an example of input waveform of a differential amplifier in the burst signal receiver when “0” signal is continuously received;

FIG. 13 shows the structure of a burst signal receiver of a seventh exemplary embodiment of the present invention; and

FIG. 14 shows the gain of a feedback circuit and a differential amplifier in the seventh exemplary embodiment.

### EXEMPLARY EMBODIMENT

### The First Exemplary Embodiment

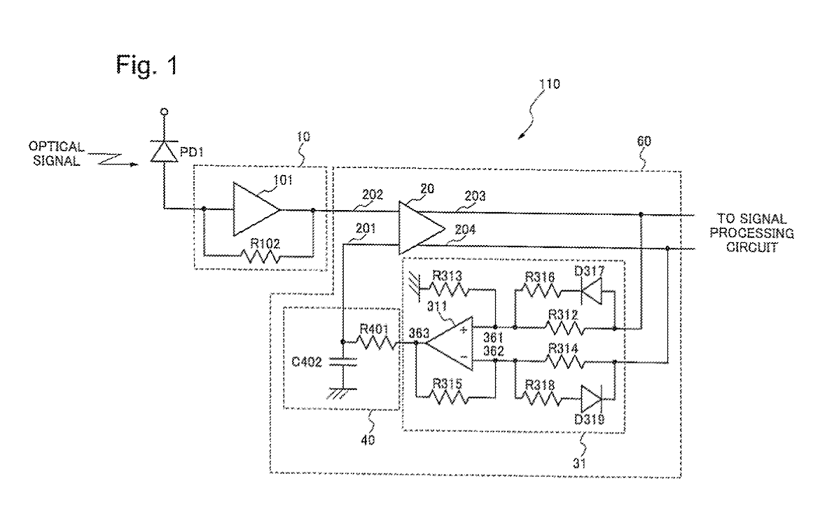

FIG. 1 shows the structure of a burst signal receiver of the first exemplary embodiment of the present invention. In a burst signal receiver 110 shown in FIG. 1, photodiode PD1 is an optical-to-electrical conversion device which converts the received optical input signal into the electric current. A transimpedance amplifier 10 converts the electric current converted in photodiode PD1 into voltage signal using resistor R102 and an inverting amplifier 101. The differential amplifier 20 inputs the voltage signal output from the transimpedance amplifier 10 and the output signal of a low pass filter 40. An error signal amplification circuit 31 is a nonlinear amplification circuit which inputs the differential output of the differential amplifier 20 and includes an operational amplifier 311, resistors R312-R316, R318 and diodes D317, D319. The low pass filter 40 includes a resistor R401 and a capacitor C402. Output 363 of the operational amplifier 311 is supplied to the differential amplifier 20 via the low pass filter 40.

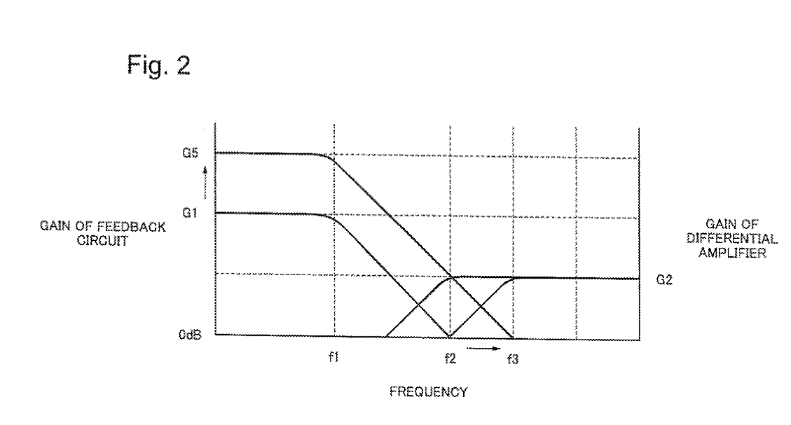

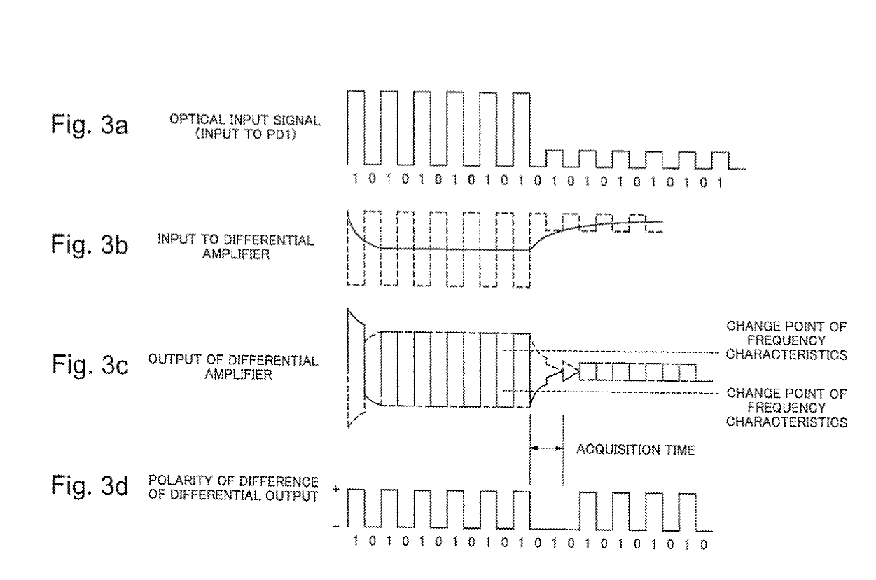

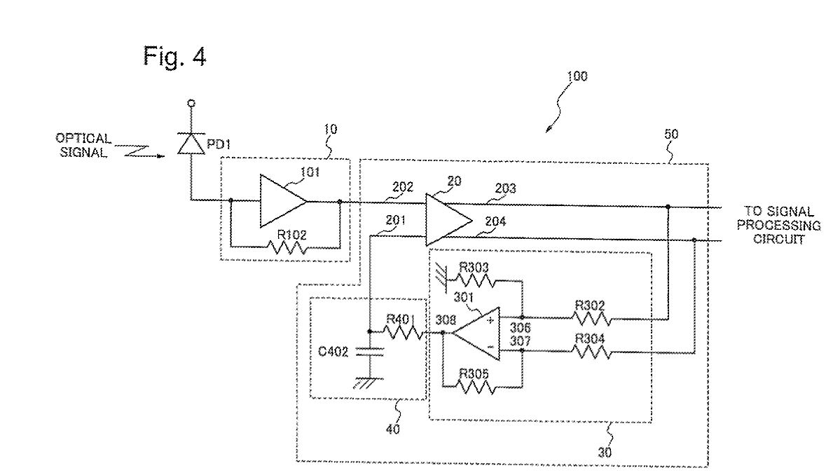

Operation of the burst signal receiver 110 will be described using FIG. 1, FIG. 2 and FIG. 3a to FIG. 3d. A different point between the burst signal receiver 100 described in FIG. 4 and the burst signal receiver 110 is only the error signal amplification circuit 31 in FIG. 1. Hence, detailed explanations of the configuration and operation which are common in FIG. 4 and FIG. 1 are omitted.

In the burst signal receiver 110 of the first exemplary embodiment, the error signal amplification circuit 30 in FIG. 4 is replaced by the error signal amplification circuit 31. As a result, the burst signal receiver 110 can respond to the burst signal quicker.

The error signal amplification circuit 31 of the burst signal receiver 110 shown in FIG. 1 includes the operational amplifier 311, resistors R312-R316, R318 and diodes D317, D319. A non-inverting input terminal 361 of the operational amplifier 311 is connected to the positive phase output terminal 203 of the differential amplifier 20 via resistor R312. The non-inverting input terminal 361 of the operational amplifier 311 is grounded via the resistor R313.

A set of resistor 8316 and diode D317 connected in series is connected to the resistor R312 in parallel between the non-inverting input terminal 361 of the operational amplifier 311 and the positive phase output terminal 203 of the differential amplifier 20. An anode of diode D317 is connected to the positive phase output terminal 203 of the differential amplifier 20.

An inverting input terminal 362 of the operational amplifier 311 is connected to a reverse phase output terminal 204 of the differential amplifier 20 via the resistor R314. The inverting input terminal 362 of the operational amplifier 311 is also connected to an output terminal 363 of the operational amplifier 311 via the resistor R315.

A set of resistor R318 and diode D319 connected in series is connected to the resistor R314 in parallel between the inverting input terminal 362 of the operational amplifier 311 and the reverse phase output terminal 204 of the differential amplifier 20. A cathode of the diode D319 is connected to the reverse phase output terminal 204 of the differential amplifier 20.

In this way, the error signal amplification circuit 31 has nonlinear circuit including the resistors R312, R316, the diode D317, the resistors R314, R318 and the diode D319 respectively between the input of the operational amplifier 311 and the output of the differential amplifier 20.

In the state that the current does not flow through-the diodes D317 and D319, the resistance values of the resistors R312-R315 are set so that the gain of the error signal amplification circuit 31 may keep the value G3, similar to the example of FIG. 4. That is, the error signal amplification circuit 31 inversely amplifies the differential output voltage of the differential amplifier 20 with gain of G3 in the state that current does not flow through the diodes D317 and D319.

Forward direction threshold voltages of the diodes D317 and D319 are both Vth. The diodes D317 and D319 become ON state in case that the anode voltage is Vth or higher than the cathode voltage respectively, and they become OFF state in other cases.

When the voltage of the positive phase output terminal 203 of the differential amplifier 20 becomes higher than the voltage of the non-inverting input terminal 361 of the operational amplifier 311 by Vth or more, the diode D317 becomes ON state, and then the current also flows through the resistor R316. As a result, combined resistance value of the nonlinear circuit consisting of the resistors R312, R316 and the diode D317 will be almost the parallel connection resistance value of the resistors R312 and R316. When the diode D317 is in OFF state, the combined resistance value is smaller than the value at the state that no current flows through resistor R316.

The above mentioned operation is the same for the nonlinear circuit between the reverse phase output terminal 204 of the differential amplifier 20 and the inverting input terminal 362 of the operational amplifier 311. That is, when the reverse phase output terminal 204 of the differential amplifier 20 becomes lower than the voltage of the non-inverting input terminal 361 of the operational amplifier 311 by Vth or more, the diode D319 becomes ON state, and the current also flows through the resistor 318. As a result, combined resistance of the nonlinear circuit consisting of the resistors R314, R318 connected in parallel and the diode D319 will be almost the parallel connection resistance value of the resistors R314 and R318. When the diode D319 is in OFF state, the combined resistance value is smaller than the value in the state that no current flows through the resistor R318.

As a result, when the diodes D317 and D319 turn ON, the gain of the error signal amplification circuit 31 increases to more than G3. Herein, the gain of the error signal amplification circuit 31 is made to be G4 when the diodes D317 and D319 turn ON.

Next, the operation of the optical signal receiver of FIG. 1 will be described using the frequency characteristics of FIG. 2 and the waveform charts of FIG. 3a to FIG. 3d.

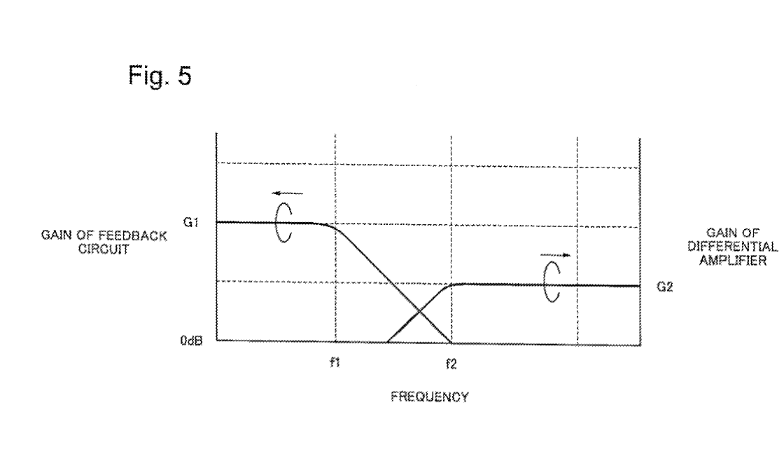

FIG. 2 shows the frequency characteristics of the feedback circuit 60 composed of the differential amplifier 20, the error signal amplification circuit 31 and the low pass filter circuit 40 in the first exemplary embodiment. The horizontal axis of FIG. 2 indicates frequency, and the vertical axis indicates the gains of the feedback circuit 60 and the differential amplifier 20. The operation of the feedback circuit 60 is same as the operation described in FIG. 5 when the diodes D317 and D319 are in OFF state, that is, the input signal level is low. That is, the gain of the feedback circuit 60 is G1 in the low frequency band. The gain decreases at the frequency higher than f1 while the gain becomes larger than 1 up to the frequency of f2.

On the other hand, the gain of the error signal amplification circuit 31 increases from G3 to G4 as before mentioned when the input voltages of the error signal amplification circuit 31 increase and the diodes D317 and D319 turn ON. As a result, the gain of the feedback circuit 60 becomes the product of G2 and G4 in the low frequency band, and the gain decreases when the frequency exceeds f1. As the result, the unity gain frequency increases to f3 which is the product of G5 and f1.

When the signal input level is small, the frequency characteristics for the gain of the differential amplifier 20 is similar to FIG. 5. However, when the signal input level is large, the gain of the differential amplifier 20 decreases at the inclination rate of 20 dB/dec in the lower frequency band than f3 although the gain keeps constant at the high frequency band by the result that the unity gain frequency of the feedback circuit 60 shifts to f3. In other words, by the result that the unity gain frequency of the feedback circuit 60, the amount of feedback increases in the low frequency band and the low frequency component of the output signal of the differential output of the differential amplifier 20 decreases. In this way, the low cutoff frequency of the differential amplifier 20 changes according to the input signal amplitude in the burst signal receiver 110 of the first exemplary embodiment.

FIG. 3a to FIG. 3d indicate signal waveforms in each part of a burst signal receiver 110 of the first exemplary embodiment. FIG. 3a to FIG. 3d show the signal waveforms in each part of the burst signal receiver 110, the horizontal direction indicates time. FIG. 3a is a waveform of an optical input signal to photodiode PD1. FIG. 3b is an input waveform of the differential amplifier 20 and FIG. 3c is an output waveform of the differential amplifier 20. Herein, solid lines in FIGS. 3b and 3c indicate waveforms of non-inverting input-positive phase output terminals 201 and 203 of the differential amplifier 20 while broken lines indicate waveforms of the inverting input-reverse phase output terminals 202 and 204. While the output of the differential amplifier 20 exceeds the predetermined amplitude, the diodes D317 and D319 become ON state. As a result that the diodes D317 and D319 become ON state, the low cutoff frequency of the differential amplifier 20 increases.

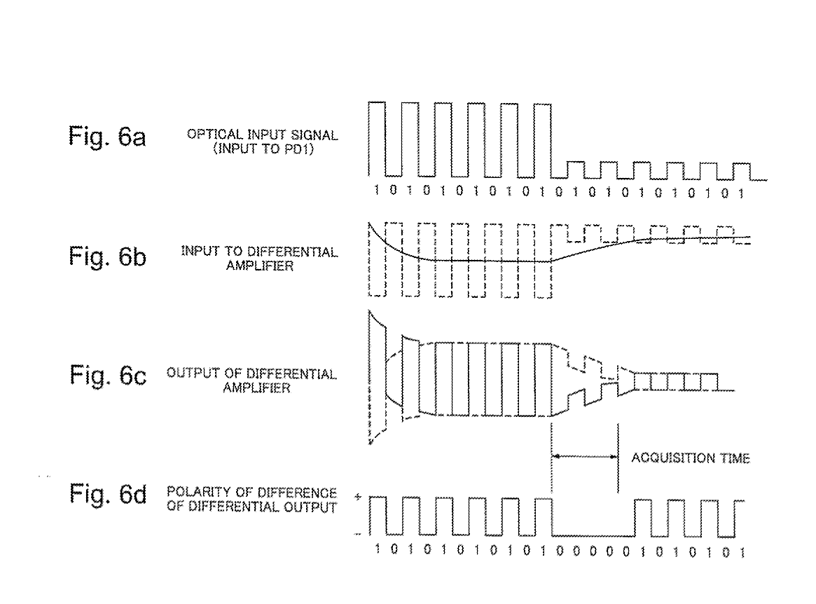

By the result that the low cutoff frequency of the differential amplifier 20 increases, the low frequency component included in the input feedback signal to the positive phase,input terminal 201 of the differential amplifier 20 decreases and the response speed of the feedback increases. As a result, the acquisition time of the burst signal response is reduced. The behavior is shown in FIG. 3c. Frequency characteristics change point shown in FIG. 3c indicates the amplitude point where the diodes D317 and D319 turn ON and the unity gain frequency of the feedback circuit 60 gets higher when the amplitude becomes larger than the point. In the first exemplary embodiment, the feedback signal response is accelerated when the output amplitude of the differential amplifier 20 is larger than the frequency characteristics change point. As a result, the acquisition time shown in FIG. 3c becomes shorter than the acquisition time shown in FIG. 6c. By shortening the acquisition time, the possibility of false detection for received data is reduced during the acquisition time.

Here, the output amplitude of the differential amplifier 20 with which the diodes D317 and D319 become ON is determined by the threshold voltage Vth of the diodes D317 and D319. It is possible to set the gain of the feedback circuit by the resistance value.

In this way, the burst signal receiver of the first exemplary embodiment of the present invention accelerates the response of the error signal amplification circuit by increasing the gain of the feedback circuit and the feedback amount of the low frequency component. As a result, the burst signal receiver of the first exemplary embodiment of the present invention can reduce the acquisition time of the received signal with small amplitude just after the large amplitude signal is inputted. Besides, the burst signal receiver of the first exemplary embodiment of the present invention offers the effect that the false detection for received data can be reduced even though the response speed of the feedback signal is set relatively low in order to improve the receiver tolerance for the data in which the same polarity signal continues.

### The Second Exemplary Embodiment

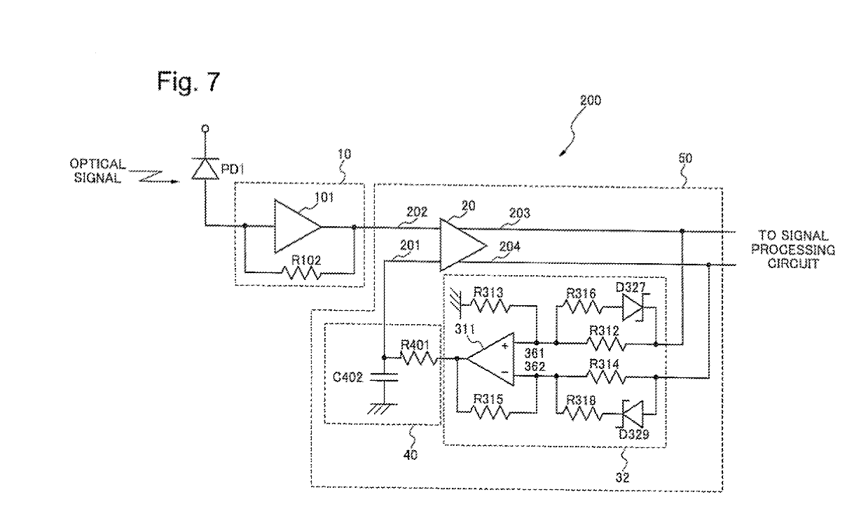

FIG. 7 shows the structure of a burst signal, receiver of the second exemplary embodiment of the present invention. In the second exemplary embodiment, zener diodes D327 and D329 are used in replace of the diodes D317 and D319 in the first exemplary embodiment.

In the following exemplary embodiments, the detail explanations in the individual embodiments are omitted since the operations of the circuits or devices with the same code number are similar in the description of their first appearances mentioned before, respectively.

A zener diode has the characteristic that break-down takes place and the current flows in the reverse direction when the reverse direction voltage exceeds the zener voltage Vz. Accordingly, in a burst signal receiver 200 shown in FIG. 7, the zener diode D327 breaks down and the current also flows through the resistor R316 when the output voltage of the positive phase output terminal 203 of the differential amplifier 20 becomes higher than the voltage of the non-inverting input terminal 361 of an operational amplifier 311 by zener voltage Vz or more. As a result, the combined resistance of the circuit consisting of the resistors R312, R316 and diode D317 becomes smaller than the resistance in the state that zener diode D317 is not breaking down.

The above mentioned operation is also similar to the circuit which connects a reverse phase output terminal 204 of the differential amplifier 20 and a inverting input terminal 362 of the operational amplifier 311. That is, the zener diode D329 breaks down and the current also flows thorough the resistor 318 when the voltage of the reverse phase output terminal 204 of the differential amplifier 20 becomes lower than the voltage of the inverting input terminal 362 of the operational amplifier 311 by zener voltage Vz. As a result, the combined resistance of the circuit consisting of resistors R314, R318 and the zener diode D329 becomes smaller than the resistance in the case that zener diode D329 does not break down.

As a result, the low cutoff frequency of the burst signal receiver 200 of the second exemplary embodiment increases as the explanation using FIG. 2 of the first exemplary embodiment that the output level of the differential amplifier 20 becomes higher. The signal acquisition time can be reduced for the burst signal receiver 200 of the second exemplary embodiment due to the same operation as in the first exemplary embodiment when small amplitude signal is inputted just after the large amplitude signal is received. And the burst signal receiver 200 in the second exemplary embodiment of the present invention offers the effect that the false detection for received data can be reduced even though the response speed of the feedback signal is set relatively low in order to improve the receiver tolerance for the data in which the same polarity signal continues.

There exist many kinds of zener diodes whose breakdown voltages are different. Accordingly, the burst signal receiver of the second to exemplary embodiment also offers the effect that the operational conditions of burst signal receiver 200 can be set in detail by selecting and using a zener diode with the breakdown voltage which is closer to the target conditions.

Further, in the first and the second exemplary embodiments, a diode or a zener diode is employed as the device which conducts when electric voltage difference between both ends of the device increases. However, it is obvious that the same effect as the first and the second exemplary embodiments can be obtained by employing other devices than diodes or zener diodes which have the characteristic that they conduct when the electric voltage difference between both ends increases. As other devices equipped with the characteristic that they conducts when the electric voltage difference between both ends increases, a varistor can be mentioned, for example. However, devices which can be applied to the present invention are not limited in these devices.

### The Third Exemplary Embodiment

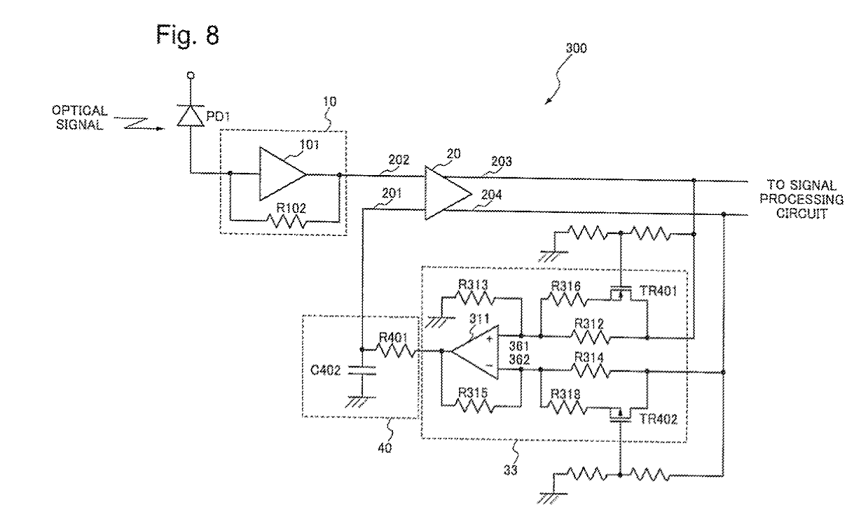

FIG. 8 shows the structure of a burst signal receiver of the third exemplary embodiment of the present invention. In a burst signal receiver 300 of the third exemplary embodiment, field effect transistors TR401 and TR402 are included instead of the diodes D317 and D319 in the first exemplary embodiment. A field effect transistor TR401 is N-channel MOS-FET (Metal Oxide Semiconductor-Field Effect Transistor) and a field effect transistor TR402 is P-channel MOS-FET. Drains of the field effect, transistors TR401 and TR402 are connected to the differential output of the differential amplifier 20, and sources of field effect transistors TR401 and TR402 are connected to the resistors R316 and R318 respectively. The voltage which is obtained by dividing differential output of the differential amplifier 20 with. resistors is applied to gates of the field effect transistors TR401 and TR402.

In the burst signal receiver 300 shown in FIG. 8, the field effect transistors TR401 and TR402 conduct between their drains and sources, and current flows through the resistors R316 and R318 when the amplitude of the differential output of the differential amplifier 20 increase and the gate voltage of the field effect transistors TR401 and TR402 exceed the respective threshold voltage of the field effect transistors. When electric current flows through the resistors R316 and R318, the gain of the error signal amplification circuit 33 increases by the same operation as the first and the second exemplary embodiments.

As a result, the low cutoff frequency increases as is explained using FIG. 2 when the output level of the differential amplifier 20 in the burst signal receiver 300 of the third exemplary embodiment becomes high, similar to the first and second exemplary embodiments. And the burst signal receiver 300 in the third exemplary embodiment as well as in the first exemplary embodiment offers the effect that the false detection for received data can be reduced even though the response speed of the feedback signal is set relatively low in order to improve the receiver tolerance for the data in which the same polarity signal continues.

Further, the current which flows through the resistors R316 and R318 is controlled by MOS-FET in order to change the gain of the error signal amplification circuit 33 in the third exemplary embodiment. However, it is also possible to offer the same effect by using junction FET, transistor or analog switch instead of MOS-FET.

### The Fourth Exemplary Embodiment

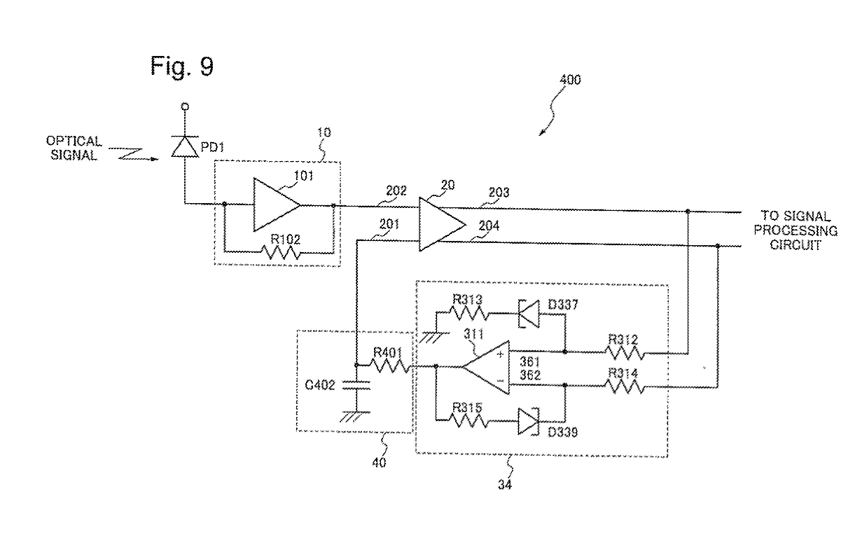

FIG. 9 shows the structure of a burst signal receiver of the fourth exemplary embodiment of the present invention. In a burst signal receiver 400 of the fourth exemplary embodiment, tunnel diodes D337 and D339 are connected in series to the resistors R313 and R315, respectively, of which the error signal amplification circuit 31 is composed. Tunnel diode is equipped with the property that the forward current flowing through the tunnel diode decreases when the voltage between both ends of the tunnel diode increases in a predetermined voltage region. This voltage region is called negative resistance region. In the fourth exemplary embodiment, the circuit constant is set so that tunnel diodes D337 and D339 may operate in the negative resistance region in the range of the output amplitude of the differential amplifier 20.

In the negative resistance region, the forward current flowing through the tunnel diodes D337 and D339 decreases along with increasing of the forward voltage of the tunnel diodes D337 and D339. Accordingly, the forward current flowing through tunnel diodes D337 and D339 decreases along with increasing of the output amplitude of the differential amplifier 20.

Here, decreasing of the current flowing through the tunnel diodes D337 and D339 is equivalent to increasing of the resistance values of the resistors R313 and R315. Accordingly, the gain of the error signal amplifier 34 increases when the current flowing through tunnel diodes D337 and D339 decreases.

As a result, the low cutoff frequency of a burst signal receiver 400 in the fourth exemplary embodiment also increases when the output level of the differential amplifier 20 becomes high as well as in the first and second exemplary embodiments. Accordingly, the burst signal receiver 400 in the fourth exemplary embodiment as well as in the first exemplary embodiment also offers the effect that the false detection for received data can be reduced even though the response speed of the feedback signal is set relatively low in order to improve the receiver tolerance for the data in which the same polarity signal continues.

Further, the current which flows through the resistors R313 and R315 is controlled by the tunnel diode as the device equipped with the negative resistance characteristic in order to change the gain of the error signal amplification circuit 34 in the fourth exemplary embodiment. However, it is also possible to offer the same effect as the fourth exemplary embodiment by using the other devices with the negative resistance characteristics instead of tunnel diode.

### The Fifth Exemplary Embodiment

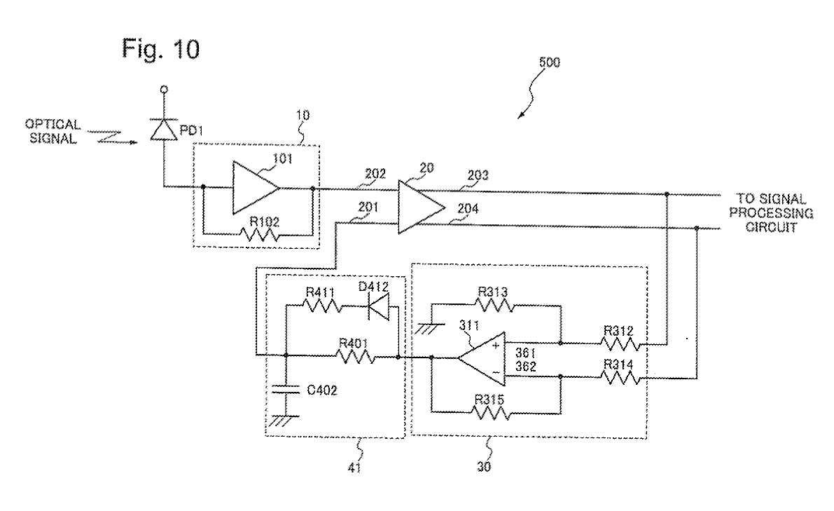

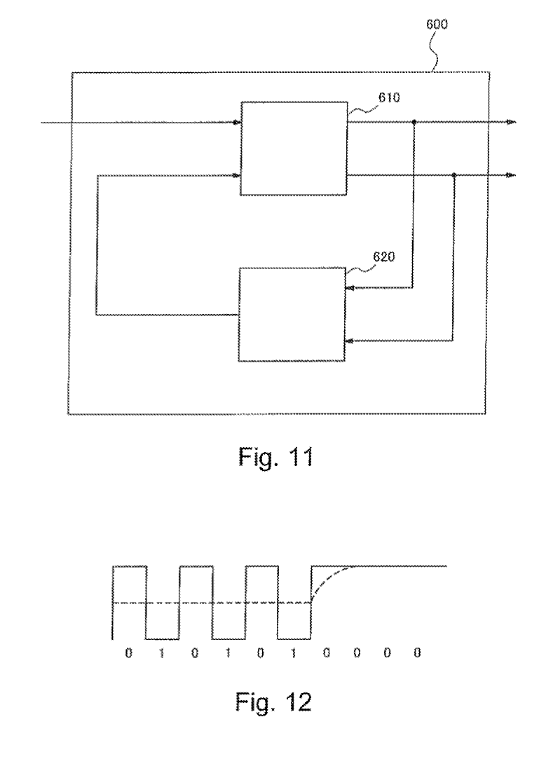

FIG. 10 shows the structure of a burst signal receiver of the fifth exemplary embodiment of the present invention. In a low pass filter 41 of a burst signal receiver 500 of the fifth exemplary embodiment, a serial connection set of diode D412 and resistor R411 is connected to resistor R401 in parallel.

When the output voltage of the error signal amplification circuit 30 increases along with the increase of the output of the differential amplifier 20 and the voltage between both ends of diode the D412 become higher than the threshold voltage Vth, the diode D412 becomes ON state and the current also flows through the resistor R411. As the result, the combined resistance of the circuit including the resistors R401, R411 and the diode D412 will be almost the parallel connection resistance of the resistor R401 and the resistor R411. The combined resistance value is smaller than the value in the state that the diode D412 is OFF, that is, in the state that no current flows through resistor R411.

Cutoff frequency f of the first order low pass filter including a capacitor of the capacitance C and a resistor of the resistance value R is given by f=1/(2πCR). Accordingly, in the fifth exemplary embodiment, the cutoff frequency of the low pass filter 41 increases because the resistance value R in the above mentioned equation decreases when the diode D412 turns ON. As a result, the same effect is brought as in the case that the unity gain frequency of the low pass filter increases in FIG. 2. Accordingly, the low cutoff frequency also increases in the burst signal receiver of the fifth exemplary embodiment when the output level of the differential amplifier 20 becomes high.

Accordingly, the burst signal receiver 500 in the fifth exemplary embodiment as well as in the first exemplary embodiment also offers the effect that the false detection for received data can be reduced even though the response speed of the feedback signal is set relatively low.

In the fifth exemplary embodiment, the cutoff frequency of the low pass filter increases by reducing the resistance value of the resistance in the low pass filter 41 when the output of the differential amplifier becomes high. However, the cutoff frequency of the low pass filter may increase by reducing the capacitance value of the capacitor C402 in the low pass filter 41 when the output of the differential amplifier becomes high. This can be realized by using variable capacitance diode instead of the capacitor C402, for example.

As described in second and third exemplary embodiments, it is obvious that the same effect as in the fifth exemplary embodiment is also obtained by using the zener diode, the field effect transistor, the transistor or the analog switch instead of diode D412.

### The Sixth Exemplary Embodiment

FIG. 11 shows the structure of a feed back amplifier 600 of the sixth exemplary embodiment of the present invention. The feed back amplifier 600 includes a differential amplifier 610 equipped with differential input and differential output, and an error signal amplifier 620.

Referring to FIG. 11, the differential output of the differential amplifier 610 is connected to the input of the error signal amplification circuit 620. The output of the error signal amplifier 620 is connected to one of differential inputs of the differential amplifier 600.

When the output voltage of the differential amplifier 610 exceeds a predetermined value, the error signal amplifier 620 operates so as to decrease the gain for the lower frequency component than predetermined frequency in the output of the differential amplifier 610.

That is, when the input voltage to the differential amplifier 610 becomes large, the input voltage to the error signal amplifier 620 also becomes large for the feed back amplifier 600 of the sixth exemplary embodiment of the present invention. The error signal amplifier 620 increases the gain of the low frequency component of the output signal from the error signal amplifier 620 when the input voltage to the error signal amplifier 620 exceeds a predetermined value.

The feedback amount of the low frequency component for the differential amplifier 610 increases and the gain of the low frequency component of the differential amplifier 610 decreases when the low frequency component of the output signal from the error signal amplifier 620 increases. Since the response of the differential amplifier 610 for the large amplitude input signal is accelerated as a result, the acquisition time for the continuous amplification of the data can be prevented from becoming long for the amplification of the large amplitude signal.

Accordingly, it is possible to realize the burst signal receiver which can reduce the false detection of the received data even though the response speed of the feedback signal set in the burst signal receiver is relatively small by applying the feedback amplifier 600 of the sixth exemplary embodiment of the present invention to an optical signal receiver with the low cutoff frequency.

### The Seventh Exemplary Embodiment

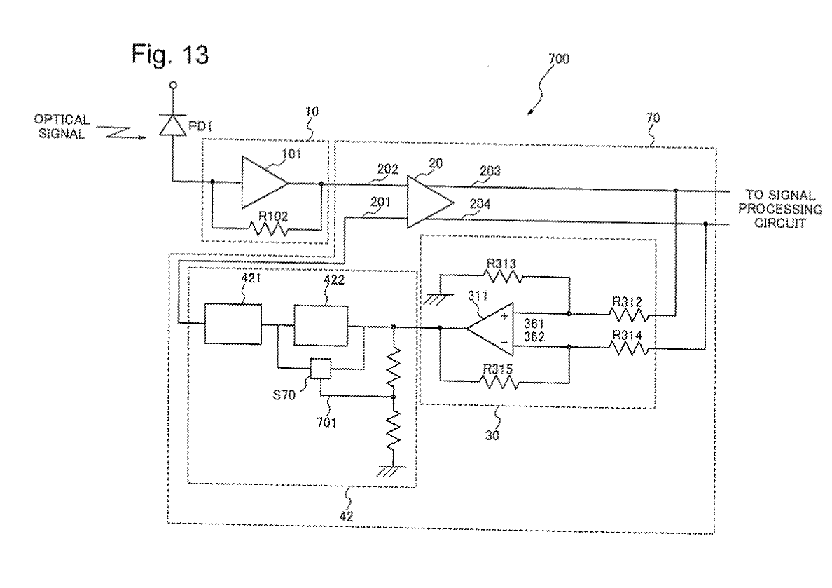

FIG. 13 shows the structure of a burst signal receiver of the seventh exemplary embodiment of the present invention.

In a burst signal receiver 700 of the seventh exemplary embodiment, a low pass filter 42 consists of low pass filters 421 and 422 which are connected in series. An analog switch S70 is connected to the low pass filter 422 in parallel. The voltage obtained by dividing the output of the error signal amplification circuit 30 with resistors is applied on a control terminal 701 of the analog switch S70. When the voltage applied on the control terminal 701 becomes higher than the switch ON voltage Von of the analog switch S70, the analog switch S70 becomes ON state.

When the output voltage of the differential amplifier 20 is low, the analog switch S70 is in OFF state since the output voltage of the error signal amplification circuit 30 is also low. Accordingly, the output of the error signal amplification circuit 30 passes through the low pass filters 421 and 422 and then is outputted when the output voltage of the differential amplifier 20 is low. In this case, the characteristics of the low pass filter 42 becomes the same as a low pass filter that is configured to connect low pass filters 421 and 422 in series. For example, when the low pass filters 421 and 422 have the same cutoff frequency f1 and both of those attenuation characteristics are −20 dB/dec, the attenuation ratio of the low pass filter 42 becomes −40 dB/dec.

When the output of the differential amplifier 20 increases and the output voltage of the error signal amplification circuit 30 increases, the voltage applied on a control terminal 701 also increases. When the voltage applied on the control terminal 701 becomes higher than ON state voltage Von of the analog switch S70, the analog switch S70 becomes ON state. As a result, the current which is flowing through a low pass filter 422 begins to flow. through the analog switch S70.

When the analog switch S70 becomes ON state, the characteristics of the low pass filter 42 is given by only the characteristics of the low pass filter 421. That is, in the case that both of the attenuation characteristics of the low pass filters 421 and 422 are −20 dB/dec, the attenuation ratio of the low pass filter 42 changes from −40 dB/dec to −20 dB/dec in the higher frequency than the cutoff frequency when the analog switch S70 turns on.

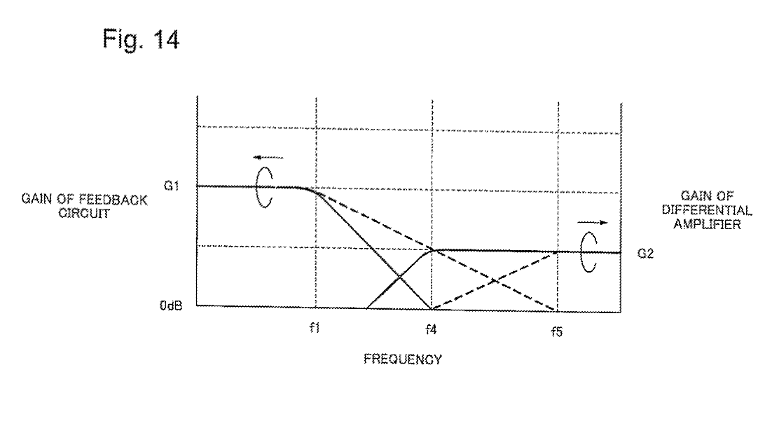

FIG. 14 shows an example of the gain characteristics of the differential amplifier 20 and the feedback circuit 70 composed of the differential amplifier 20, the error signal amplification circuit 30 and the low pass filter 42 in the seventh exemplary embodiment. In FIG. 14, the cutoff frequency of the low pass filters 421 and 422 is f1, and the attenuation characteristics in the frequency band more than f1 is −20 dB/dec. In FIG. 14, solid lines indicate the case that the analog switch S70 is in OFF state while broken lines indicate the case that the analog switch S70 is in ON state. The unity gain frequency of feedback circuit 71 increases to f5 from f4 since the attenuation ratio characteristics of the low pass filter 42 changes from −40 dB/dec to −20 dB/dec when the analog switch S70 changes from OFF state to ON state. Hence, the feedback amount of the low frequency band to the differential amplifier 20 increases, and the gain in low frequency band of the differential amplifier decreases. That is, the component of the low frequency band included in the differential amplifier 20 decreases when the output level of the differential amplifier 20 becomes high in the burst signal receiver of the seventh exemplary embodiment.

Accordingly, even if the response speed of the feedback signal is also set to be relatively small in the burst signal receiver 700 of the seventh exemplary embodiment, similar to the burst signal receivers of the 1st-the 5th exemplary embodiments, the effect is obtained that the false detection of received data can be reduced.

Further, the structure of the low pass filter 42 of the seventh exemplary embodiment is not limited to an example of the above mentioned description. It is obvious to obtain the same effect as the above mentioned if the low pass filter 42 has the characteristics that the attenuation ratio decreases when the output level of the differential amplifier 20 becomes high.

While the invention has been particularly shown and described with reference to exemplary embodiments thereof, the invention is not limited to these embodiments. It will be understood by those of ordinary skill in the art that various changes in form and details may be made therein without departing from the spirit and scope of the present invention as defined by the claims.

The whole or part of the exemplary embodiments disclosed above can be described as, but not limited to, the following supplementary notes.

(Supplementary note 1) A feedback amplifier comprising:
a differential amplifier equipped with differential input terminals and differential output terminal; and
a first amplifier,

wherein

said differential output terminal is connected to input terminal of said first amplifier;

output terminal of said first amplifier is connected to one of said differential input terminals; and

the gain of said first amplifier decreases for lower frequency component of the signal which said differential amplifier outputs than a predetermined frequency when the output voltage of said differential output exceeds a predetermined value.

(Supplementary note 2) The feedback amplifier according to Supplementary note 1, wherein:

said first amplifier includes an error signal amplifier and a low pass filter;

said differential output terminal is connected to input terminal of said error signal amplifier;

the output terminal of said error signal amplifier is connected to one of said differential input terminals via said low pass filter; and

the gain of said error signal amplifier increases when input voltage of said error signal amplifier exceeds a predetermined value.

(Supplementary note 3) The feedback amplifier according to Supplementary note 1, wherein:

said first amplifier includes an error signal amplifier and a low pass filter;

said differential output terminal is connected to input terminal of said error signal amplifier;

the output terminal of said error signal amplifier is connected to one of said differential input terminals via said low pass filter; and

the cutoff frequency of said low pass filter increases when input voltage to said error signal amplifier exceeds the predetermined value.

(Supplementary note 4) The feedback amplifier according to Supplementary note 1, wherein:

said first amplifier includes an error signal amplifier and a low pass filter;

said differential output terminal is connected to input terminal of said error signal amplifier;

the output terminal of said error signal amplifier is connected to one of said differential input terminals via said low pass filter; and

the attenuation rate of said low pass filter decreases in the frequency higher than the cutoff frequency of said low pass filter when input voltage to said error signal amplifier exceeds the predetermined value.

(Supplementary note 5) The feedback amplifier according to Supplementary note 2, wherein:

said error signal amplifier includes nonlinear circuit having resistance values which specify said gain of said error signal amplifier; and

the resistance values of said nonlinear circuit change when input voltage to said error signal amplifier exceeds said predetermined value.

(Supplementary note 6) The feedback amplifier according to Supplementary note 5, wherein:

said error signal amplifier further comprises an operational amplifier;

said nonlinear circuit includes a circuit in which a first resistor and a diode are connected in series and a second resister;

said circuit and said second resistor are connected in parallel;

said nonlinear circuit is placed between said differential amplifier and said operational amplifier; and

said diode turns on when input voltage of said error signal amplifier exceeds said predetermined value.

(Supplementary note 7) The feedback amplifier according to Supplementary note 6, wherein

said diode is a zener diode.

(Supplementary note 8) The feedback amplifier according to Supplementary note 1, wherein:

a light receiving element and a transimpedance amplifier are further included;

said light receiving element converts a received light signal to a received photo current; and

said transimpedance amplifier converts said received photo current to voltage and supplies to the other one of said differential input terminals.

(Supplementary note 9) A feedback amplification method, comprising:

amplifying the difference between the first input and the second input and outputting the amplified difference between the first input and the second input as differential outputs;

amplifying the difference between said differential outputs and outputting the amplified difference in said differential output as the first output;

inputting said first output to said second input; and

reducing the gain of the amplifying the difference between said differential outputs for the lower frequency than a predetermined frequency of said differential output when the output voltage of said differential output exceeds a predetermined value.

(Supplementary note 10) A feedback amplifier comprising:
a differential amplifying means equipped with differential input terminals and differential output terminal; and
a first amplifying means,

wherein

said differential output terminal is connected to input terminal of said first amplifying means;

output terminal of said first amplifying means is connected to one of said differential input terminals; and

the gain of said first amplifying means decreases for lower frequency component of the signal which said differential amplifier outputs than a predetermined frequency when the output voltage of said differential output exceeds a predetermined value.

1. A feedback amplifier comprising:
a differential amplifier equipped with differential input terminals and differential output terminal; and
a first amplifier,
wherein
said differential output terminal is connected to input terminal of said first amplifier;
output terminal of said first amplifier is connected to one of said differential input terminals; and
the gain of said first amplifier decreases for lower frequency component of the signal which said differential amplifier outputs than a predetermined frequency when the output voltage of said differential output exceeds a predetermined value.

2. The feedback amplifier according to claim 1, wherein:
said first amplifier includes an error signal amplifier and a low pass filter;
said differential output terminal is connected to input terminal of said error signal amplifier;
the output terminal of said error signal amplifier is connected to one of said differential input terminals via said low pass filter; and
the gain of said error signal amplifier increases when input voltage of said error signal amplifier exceeds a predetermined value.

3. The feedback amplifier according to claim 1, wherein:
said first amplifier includes an error signal amplifier and a low pass filter;
said differential output terminal is connected to input terminal of said error signal amplifier;
the output terminal of said error signal amplifier is connected to one of said differential input terminals via said low pass filter; and
the cutoff frequency of said low pass filter increases when input voltage to said error signal amplifier exceeds the predetermined value.

4. The feedback amplifier according to claim 1, wherein:
said first amplifier includes an error signal amplifier and a low pass filter;
said differential output terminal is connected to input terminal of said error signal amplifier;
the output terminal of said error signal amplifier is connected to one of said differential input terminals via said low pass filter; and
the attenuation rate of said low pass filter decreases in the frequency higher than the cutoff frequency of said low pass filter when input voltage to said error signal amplifier exceeds the predetermined value.

5. The feedback amplifier according to claim 2, wherein:
said error signal amplifier includes nonlinear circuit having resistance values which specify said gain of said error signal amplifier; and
the resistance values of said nonlinear circuit change when input voltage to said error signal amplifier exceeds said predetermined value.

6. The feedback amplifier according to claim 5, wherein:
said error signal amplifier further comprises an operational amplifier;
said nonlinear circuit includes a circuit in which a first resistor and a diode are connected in series and a second resister;
said circuit and said second resistor are connected in parallel;
said nonlinear circuit is placed between said differential amplifier and said operational amplifier; and
said diode turns on when input voltage of said error signal amplifier exceeds said predetermined value.

7. The feedback amplifier according to claim 6, wherein
said diode is a zener diode.

8. The feedback amplifier according to claim 1, wherein:
a light receiving element and a transimpedance amplifier are further included;
said light receiving element converts a received light signal to a received photo current; and
said transimpedance amplifier converts said received photo current to voltage and supplies to the other one of said differential input terminals.

9. A feedback amplification method, comprising:
amplifying the difference between the first input and the second input and outputting the amplified difference between the first input and the second input as differential outputs;
amplifying the difference between said differential outputs and outputting the amplified difference in said differential output as the first output;
inputting said first output to said second input; and
reducing the gain of the amplifying the difference between said differential outputs for the lower frequency than a predetermined frequency of said differential output when the output voltage of said differential output exceeds a predetermined value.

10. A feedback amplifier comprising:
a differential amplifying means equipped with differential input terminals and differential output terminal; and
a first amplifying means,
wherein
said differential output terminal is connected to input terminal of said first amplifying means;
output terminal of said first amplifying means is connected to one of said differential input terminals; and
the gain of said first amplifying means decreases for lower frequency component of the signal which said differential amplifier outputs than a predetermined frequency when the output voltage of said differential output exceeds a predetermined value.
